(19) United States
(12) Patent Application Publication
(10) Pub. No.: US 2016/0033349 A1
(43) Pub. Date: Feb. 4, 2016

(54) PRESSURE SENSOR HAVING CAP-DEFINED MEMBRANE

(71) Applicant: Silicon Microstructures, Inc., Milpitas, CA (US)

(72) Inventor: Omar Abed, San Jose, CA (US)

(73) Assignee: SILICON MICROSTRUCTURES, INC., Milpitas, CA (US)

(21) Appl. No.: 14/622,576

(22) Filed: Feb. 13, 2015

Related U.S. Application Data
(60) Provisional application No. 62/030,604, filed on Jul. 29, 2014.
(60) Provisional application No. 62/090,306, filed on Dec. 10, 2014.

(51) Int. Cl. G01L 9/00; B81B 7/00

(52) U.S. Cl. CPC G01L 9/0048; G01L 9/0051; B81B 7/0016

(57) ABSTRACT

Structures and methods of protecting membranes on pressure sensors. One example may provide a pressure sensor having a backside cavity defining a frame and under a membrane formed in a device layer. The pressure sensor may further include a cap joined to the device layer by a bonding layer. A recess for a reference cavity may be formed in one or more of the cap, bonding layer, and membrane or other device layer portion. The recess may have a width that is narrower than a width of the backside cavity in at least one direction. In other examples, the recess may be shaped such that it has an outer edge that is within an outer edge of the backside cavity. This may reinforce a junction of the device layer and frame. The recess may define an active membrane spaced away from the device layer and backside cavity junction.

### CROSS-REFERENCE TO RELATED APPLICATIONS

This application is a non-provisional of U.S. provisional patent application Nos. 62/030,604, filed on Jul. 29, 2014, and 62/090,306, filed Dec. 10, 2014, which are incorporated by reference.

### BACKGROUND

Pressure sensing devices have become ubiquitous the past few years as they have found their way into many types of products. Utilized in automotive, industrial, consumer, and medical products, the demand for pressure sensing devices has skyrocketed and shows no signs of abating.

Pressure sensing devices may include pressure sensors as well as other components. Pressure sensors may typically include a diaphragm or membrane. Typically, this membrane is formed by creating the Wheatstone bridge in a silicon wafer, then etching away the silicon from the opposite surface until a thin layer of silicon is formed beneath the Wheatstone bridge. The thin layer is a membrane that may be surrounded by a thicker, non-etched silicon water portion forming a frame. When a pressure sensor in a pressure sensing device experiences a pressure, the membrane may respond by changing shape. This change in shape causes one or more characteristics of electronic components on the membrane to change. These changing characteristics can be measured, and from these measurements, the pressure can be determined.

Often, the electronic components are resistors that are configured as a Wheatstone bridge located on the membrane. As the membrane distorts under pressure, the resistance of the resistors also changes. This change results in an output of the Wheatstone bridge. This change can be measured through wires or leads attached to the resistors.

Conventional pressure sensors may be formed of a diaphragm or membrane attached to and surrounded by a frame. In some pressure sensors, the sensor may measure a pressure difference between two different locations, such as the two sides of a filter. These may be referred to as gauge pressure sensors. In other types of sensors, an output may be compared to a known, consistent pressure, which may typically be a vacuum. This type of sensor may be referred to as an absolute pressure sensor. In an absolute pressure sensor, a first side of the membrane may be exposed to the media to be measured, while a second side may be in contact with the reference chamber, which may be a vacuum chamber. The first side of the membrane exposed to the media may be subjected to high pressures.

This high pressure on the membrane may result in a highly concentrated tensile force at the frame-membrane junction. This stress may create cracks or other damage in the silicon crystal structure of the membrane. This damage may lead to errors in pressure measurements or non-functionality of the pressure sensor.

Thus, what is needed are structures and methods of protecting a membrane on a pressure sensor from damage due to high pressures.

### SUMMARY

Accordingly, embodiments of the present invention may provide structures and methods of protecting a membrane on a pressure sensor from damage due to high pressures. An illustrative example may provide a pressure sensor having a first wafer portion including a handle wafer or layer and a device wafer or layer, the handle wafer or layer having a backside cavity, the backside cavity defining a membrane in the device wafer or layer. The pressure sensor may further include a bonding layer over the membrane and a cap over or attached to the bonding layer. The bonding layer may be an oxide layer formed on the device wafer, the cap wafer, or both. In various embodiments of the present invention, a reference cavity may be formed in one or more of the membrane, the bonding layer, the cap, or other layer or portion of the pressure sensor. The reference cavity, regardless of which layer or layers in which it resides, may have a lateral or planar width that is narrower than a width of the backside cavity in at least one direction. In other embodiments, the reference cavity may be shaped such that it has an outer edge that is within an outer edge of the backside cavity. This may provide reinforcement and reduce stress at a junction of the membrane and frame. Also, the narrower reference cavity may define an active portion of the membrane such that the active portion of the membrane is spaced away from the device layer and backside cavity junction. (As used here, a membrane may be defined by a backside cavity and a frame, while a portion of the membrane, the active membrane, may be defined by a reference cavity. Also as used here, the more general term membrane may mean either membrane or active membrane, particularly where the distinction is not critical.) In various embodiments of the present invention, the device wafer or layer may be formed of a silicon wafer portion or other material, the bonding layer may comprise silicon dioxide or glass or other material, while the cap or cap layer may be formed of a silicon wafer portion, silicon dioxide or glass, or other glass, including a heat-resistant glass with a low-temperature coefficient or temperature coefficient close to that of silicon, such as a borosilicate glass including Pyrex®, which is licensed by Corning Incorporated, or other material.

Embodiments of the present invention may provide sensors that simplify manufacturing. Again, a membrane on a sensor may be fabricated by first creating a Wheatstone bridge in a silicon wafer, and then etching away the silicon beneath the Wheatstone bridge to form a thin membrane of silicon containing the Wheatstone bridge. One factor affecting the sensitivity of the device may be the proximity of the resistors of the Wheatstone bridge to the edges of the active membrane. Embodiments of the present invention may provide a pressure sensor in which the edges of an active portion of the membrane are determined by the location of the reference cavity, rather than the backside cavity cut from the back of the silicon. Because the reference cavity is much thinner than the cavity cut from the backside of the silicon, it may be easier to align the Wheatstone bridge to the edges of the active membrane during manufacturing. The relative thinness of the reference cavity may also help in controlling the size of the cavity. Moreover, the reference cavity and the Wheatstone bridge may be on the same side of the device, rather than on opposite sides, which may make them easier to align. Also, by locating the reference cavity in the device wafer or bonding layer on the device wafer, alignment during bonding may not be as critical as compared to when a reference cavity is etched into a cap layer or wafer, since this second configuration may require the alignment of two wafers during bonding.

Embodiments of the present invention may also provide pressure sensors that are protected from damage by high pressures in at least two ways. In conventional pressure sensors, the size of the membrane may be determined by the size of the cavity etched into the backside of the wafer. In various embodiments of the present invention, this restriction on the size of the backside cavity may be removed. Significantly, the size of the active portion of the membrane is no longer determined by the size of the backside cavity, and thus the size of the backside cavity can be made much larger than the size of the active portion of the membrane. As the size of the backside cavity increases, a tensile stress generated at the corner of the backside cavity may be reduced. Also, the edge of the active membrane, where the most stress is generated, is no longer proximate with the corner of the back cavity. Thus, the highest stress may not only be reduced, but the locus of the highest stress may shift to a top side corner of the active membrane, and this stress may be compressive rather than tensile. Silicon can withstand a higher compressive stress than tensile stress before fracturing, further protecting the device from damage.

Embodiments of the present invention may also limit damage caused by high pressures of fluids in the backside cavity by limiting an amount the membrane may deflect. Specifically, the reference cavity above the active portion of the membrane may have a height or thickness such that it may limit the deflection of the membrane. This may prevent the membrane from deflecting more than an amount where damage may occur due to high or excessively high pressures. In a specific embodiment of the present invention, it may be desirable that the membrane deflect a first distance during normal operation. It may also be expected that damage may occur if the membrane is allowed to deflect a second distance, the second distance greater than the first. In this example, the reference cavity may have a thickness or height such that the membrane is prevented from deflecting more than a third distance, the third distance greater than the first distance to allow desired operation, but less than the second distance to prevent damage.

In various embodiments of the present invention, various layers may be included or omitted in embodiments of the present invention. For example, an optional layer of eutectically-bondable metal or other material may be placed on the back or bottom of the device. This layer may be formed as a thin layer of gold on the back or bottom of the device for bonding purposes. This layer may facilitate bonding to a second integrated circuit device, a device package, a device enclosure, or a printed or flexible circuit board or other substrate. An optional layer of polysilicon or other material may be placed or formed on a top surface of device layer or wafer. This optional layer may be located on a top surface of the device layer and under the bonding or oxide layer. That is, optional layer may be located between device layer or wafer and bonding or oxide layer.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates a side view of a pressure sensor according to an embodiment of the present invention;

FIG. 2 illustrates a top view of a pressure sensor according to an embodiment of the present invention;

FIG. 3 illustrates a portion of a pressure sensor being manufactured according to an embodiment of the present invention;

FIG. 4 illustrates a portion of a pressure sensor being manufactured according to an embodiment of the present invention;

FIG. 5 illustrates a portion of a pressure sensor being manufactured according to an embodiment of the present invention;

FIG. 6 illustrates a portion of a pressure sensor being manufactured according to an embodiment of the present invention;

FIG. 7 illustrates a side view of a portion of a pressure sensor according to an embodiment of the present invention;

FIG. 8 illustrates a side view of a pressure sensor according to an embodiment of the present invention;

FIG. 9 illustrates a portion of a pressure sensor being manufactured according to an embodiment of the present invention;

FIG. 10 illustrates a portion of a pressure sensor being manufactured according to an embodiment of the present invention;

FIG. 11 illustrates a side view of a portion of a pressure sensor according to an embodiment of the present invention;

FIG. 12 illustrates a side view of a portion of a pressure sensor according to an embodiment of the present invention;

FIG. 13 illustrates a side view of another pressure sensor according to an embodiment of the present invention;

FIG. 14 illustrates a top view of a pressure sensor according to an embodiment of the present invention;

FIG. 15 illustrates a portion of a pressure sensor being manufactured according to an embodiment of the present invention;

FIG. 16 illustrates a side view of another pressure sensor according to an embodiment of the present invention;

FIG. 17 illustrates a top view of a pressure sensor according to an embodiment of the present invention;

FIG. 18 illustrates a portion of a pressure sensor being manufactured according to an embodiment of the present invention;

FIG. 19 illustrates a portion of a pressure sensor being manufactured according to an embodiment of the present invention;

FIG. 20 illustrates a portion of a pressure sensor being manufactured according to an embodiment of the present invention; and

FIG. 21 illustrates a side view of another pressure sensor according to an embodiment of the present invention.

### DESCRIPTION OF ILLUSTRATIVE EMBODIMENTS

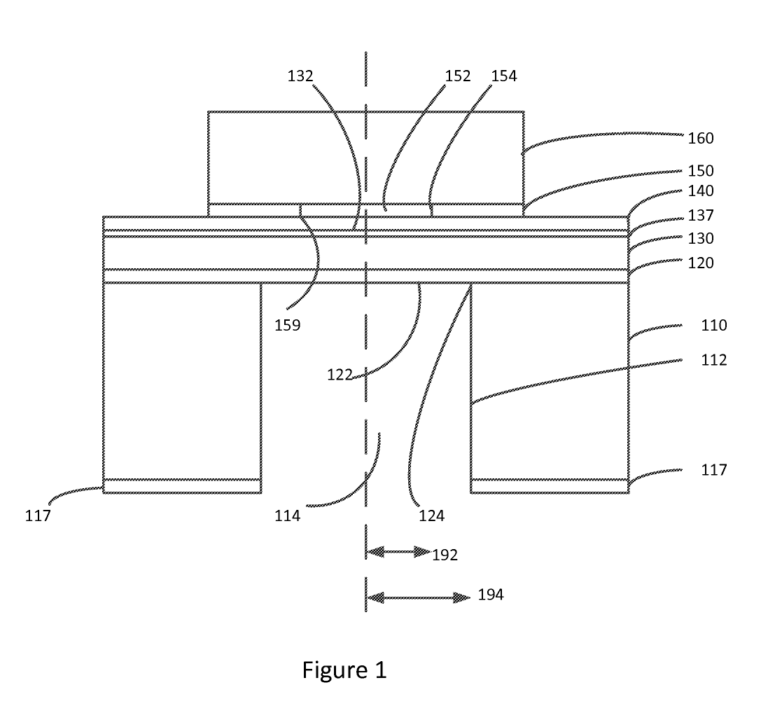

FIG. 1 illustrates a side view of a pressure sensor according to an embodiment of the present invention. This figure, as with the other included figures, is shown for illustrative purposes and does not limit either the possible embodiments of the present invention or the claims.

This pressure sensor may include cap 160 attached to a top of a first wafer portion of a pressure sensor, where the first wafer portion further includes device wafer or layer 130 and handle wafer or layer 110. Device wafer of layer 130 may be supported by handle wafer or layer 110. Handle wafer or layer 110 may include a backside cavity 114 defining an edge of sidewall 112. Backside cavity 114 may extend from a bottom surface of handle wafer or layer 110 to a bottom 122 of oxide layer 120. Device layer 130 may have one or more electrical components 132 formed in its top surface. Electrical components 132 may be protected by oxide layer 140.

Cap 160 may include oxide layer 150 on a bottom surface, though oxide layer 150 may be omitted in various embodiments of the present invention. Cap 160 may be attached to device layer 130 by fusion bonding oxide layer 150 to oxide layer 140. Where one or more oxide layers 140 or 150 are omitted, cap 160 may be attached to device layer 130 by fusion bonding cap 160 to oxide layer 140, by fusion bonding oxide layer 150 to device layer 130, or by fusion bonding cap layer 160 directly to device layer 130. Oxide layer 150 may be etched before fusion bonding to form a recess, which may form reference cavity 152. Reference cavity 152 may be defined by outer edge 154. While reference cavity 152 is formed in oxide layer 150, in this and other embodiments of the present invention, reference cavity 152 may be formed in oxide layer 150 and cap layer 160, in oxide layer 150 and oxide layer 140, in device layer 130, or in any combination thereof.

Reference cavity 152 may have a width that is narrower than a width of backside cavity 114 in at least one direction. Specifically, a distance 192 from a center line of the pressure sensor to an edge 154 of reference cavity 152 may be shorter than a distance 194 from a center line to an edge 112 of backside cavity 114. In this way, an active portion of a membrane defined by edge 154 may be narrower than the membrane defined by edge 112. In various embodiments of the present invention, an outside edge of reference cavity 152 may be inside of an edge of backside cavity 114, where the edges are considered vertically in this and other embodiments.

In conventional pressure sensors, cap 160 may be absent. In such case, as a membrane or diaphragm formed by a backside cavity deflects, a junction point between a diaphragm and frame may experience a large tensile force. In this figure, if cap 160 were absent, this force would be concentrated at location 124. This concentration of force may result in cracks or other damage at or near location 124.

Accordingly, embodiments of the present invention may provide a cap or other reinforcing structure, such as cap 160, where a reference cavity, such as reference cavity 152, may be narrower than a backside cavity, such as backside cavity 114. In this case, location 124 may be reinforced by cap 160. Also, the location of highest stress may move from the location 124 to location 159. The stress at location 159 is compressive when pressure is applied to the underside of membrane 122, rather than tensile. Further, even when one or more cracks or other damage appears at or near location 124, the cracks are away from the active membrane area, which is defined by reference cavity 152.

Also, in conventional pressure sensors, a membrane or diaphragm may deflect an amount that may cause damage to the pressure sensor. This may occur due to the presence of unforeseen high pressures of fluids in the backside cavity, or by another event.

Accordingly, embodiments of the present invention may provide a reference cavity having height or thickness that limits a maximum deflection of the active membrane. In various embodiments of the present invention, this height or thickness may be such that an active membrane may be able to deflect enough for desired operation, but not enough to cause damage to the pressure sensor. Specifically, edge 154 may have a height that allows the active membrane to deflect enough for proper operation of the pressure sensor, but not enough to cause damage or rupture the membrane. Instead, the active membrane deflects such that it reaches a top of the reference cavity 52 and cannot any further even if the pressure continues to increase, preventing damage from being caused. That is, the top of the reference cavity 152 may act as a deflection stop to prevent damage to the pressure sensor. In various embodiments of the present invention, the topside of reference cavity 152, the underside of cap 160, may include one or more bosses or other structures that may determine a height of the reference cavity 152 and the maximum deflection of the active membrane.

In various embodiments of the present invention, the structures used in pressure sensors may have various sizes and width. For example, handle wafer or portion may have a thickness of 250 to 600 microns, though it may be thinner than 250 or thicker than 600 microns. Device wafer or layer 130 may be considerable thinner since it forms the membrane. This thickness may be 15-25 microns, though it may be thinner than 15 or thicker than 25 microns. The cap wafer or layer 160, and other cap wafer or layers, may have a thickness that is at least approximately 150 microns, though it may be narrower or thicker than 150 microns. The buried or bonding oxide layers 120, 140, and 150 may have a thickness between 0.1 and 3 microns, though they may be thinner or thicker than this range. The reference cavity 136, as with the other reference cavities in other embodiments of the present invention, may have a thickness or height of 100 nm to 500 nm, though in other embodiments may it may be from 50 m to 1000 nm. A specific embodiment of the present invention may have a reference cavity having a height of 4000 A.

In this and other embodiments of the present invention, an optional layer 117 of eutectically-bondable metal or other material may be placed on the back or bottom of handle wafer 110. This layer may be formed as a thin layer of gold on the back or bottom of the device for bonding purposes. Layer 117 may facilitate bonding to a second integrated circuit device, a device package, a device enclosure, or a printed or flexible circuit board or other substrate. Optional layer 117 has been omitted from the other figures for clarity.

In this and other embodiments of the present invention, an optional layer 137 of polysilicon or other material may be placed or formed on a top surface of device layer or wafer 110. Optional layer 137 may be located on a top surface of the device layer 130 and under the bonding or oxide layer 140. That is, optional layer 137 may be located between device layer or wafer 130 and bonding or oxide layer 140. Polysilicon layer 137 may provide a field shield to stabilize the electrical performance of the resistors or other components 132 on the top surface of device layer 130. Optional layer 137 has been omitted from the other figures for clarity.

Again, reference cavity 152 may have a width that is narrower than a width of the backside cavity 114 in at least one direction. In this in other embodiments, reference cavity 152 may be sized and aligned such that it fits within the outer boundaries of backside cavity 114. The result may be that the device membrane is defined in size by recess 152 in cap 160, instead of backside cavity 114, as is conventional. An example is shown in the following figure.

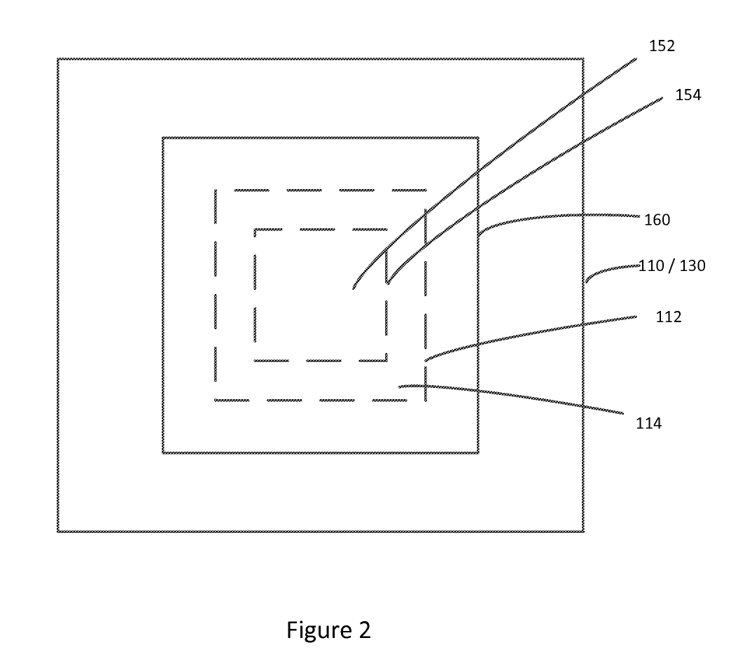

FIG. 2 illustrates a top view of a pressure sensor according to an embodiment of the present invention. Again, cap 160 may be placed on a first wafer portion including handle wafer or layer 110 and device wafer or layer 130. In this example, recess 152 may have edges 154 that are arranged to fit within edges 112 of backside cavity 114. In this example, recess 152 may define the area of the pressure sensor's active membrane. In various embodiments of the present invention, the active membrane may have various sizes. For example, it may be 240 by 240 microns in size. The active membrane thickness may be on the order of 20 microns. Such a membrane or diaphragm may support and be able to measure pressures up to 20 bar, 120 bar, or more.

The various layers shown here may be omitted, and others may be included consistent with embodiments of the present invention. A specific example of a method of manufacturing an embodiment of the present invention is shown in the following figures.

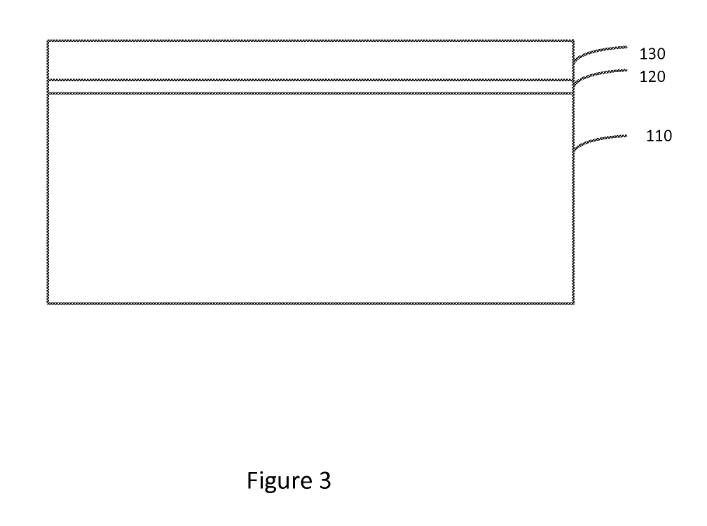

FIG. 3 illustrates a first wafer portion according to an embodiment of the present invention. This wafer portion may include device wafer or layer 130 and handle wafer or layer 110 joined by oxide layer 120 and then thinned. In various embodiments of the present invention, such a structure may be commercially available. In other embodiments of the present invention, oxide layer 120 may be grown on a first wafer 110. A second or device wafer 130 may be fusion bonded to a top side of oxide layer 120. Device wafer 130 may also include an oxide layer, not shown, or oxide layer 120 may be grown on a bottom side device wafer 130. In still other embodiments of the present invention, device layer 130 may be grown as an epitaxial layer on oxide layer 120.

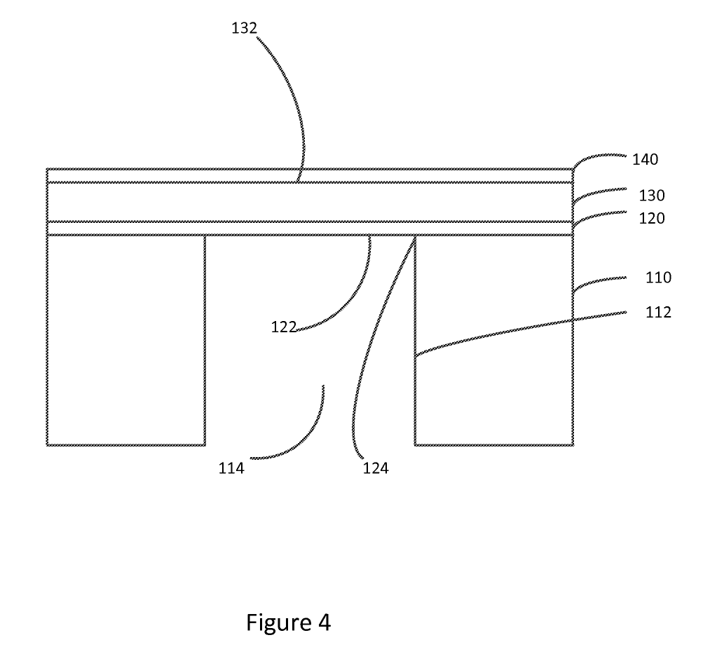

In FIG. 4, backside cavity 114 may be formed. Backside cavity 114 may be formed by etching, for example by using deep reactive-ion etching (DRIE), micromachining, or other technique. Backside cavity 114 may extend from a bottom of handle wafer or layer 110 to a bottom 122 of buried oxide layer 120. One or more electrical components 132 may be placed on, or formed in or on, a top surface of device wafer 130. For example, piezoelectric resistors may be implanted or diffused in a top surface of device wafer or layer 130. Interconnect traces may be formed on the top surface of device wafer or layer 130. An oxide layer or bonding layer 140 may be grown over device layer 130. This oxide layer 140 may help to protect components 132.

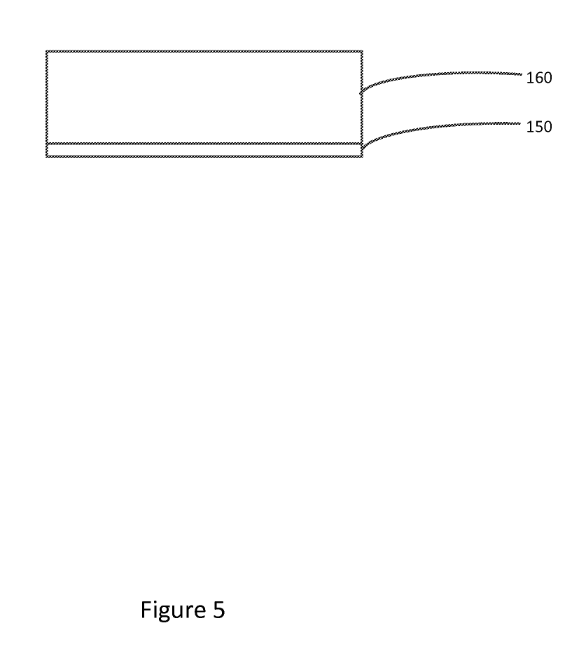

In FIG. 5, cap 160 may be provided. An oxide layer 150 may be grown on a bottom side of cap 160.

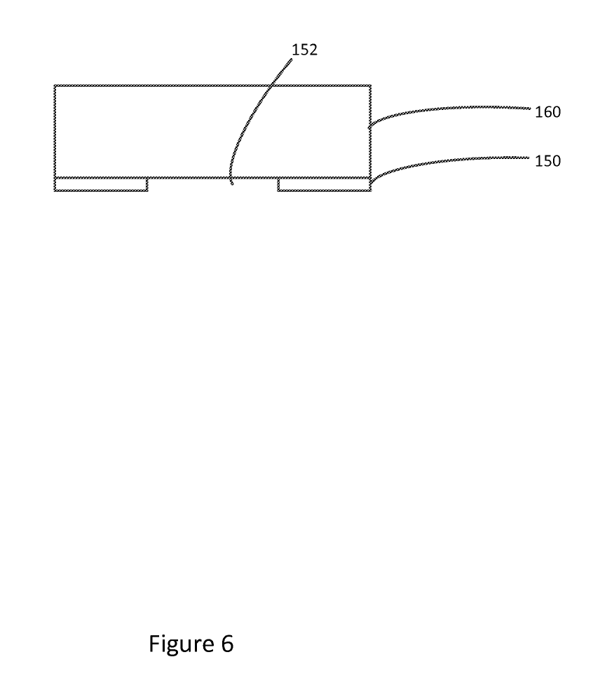

In FIG. 6, an opening 152 may be etched in oxide layer 150 on bottom side of 160. The resulting cap may be attached to the structure in FIG. 4 to produce a pressure sensor shown in FIG. 1.

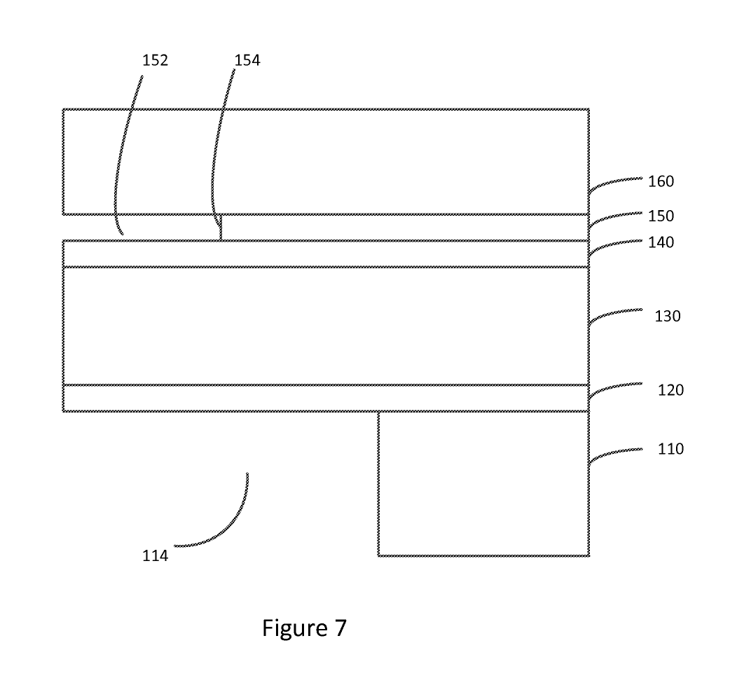

FIG. 7 illustrates a side view of a portion of a pressure sensor according to an embodiment of the present invention. Again, a handle wafer 110 may support a device layer wafer 130. A buried oxide layer 120 may be located between handle wafer portion 110 and device wafer portion 130. Backside cavity 114 may extend from a bottom side of handle wafer 110 to a bottom side 122 of oxide layer 120. Oxide layer 140 may be grown on top of device wafer 130, and an oxide layer 150 may be grown on a bottom side of cap wafer or layer 160, though in various embodiments of the present invention, one or more oxide layers 140 or 150 may be omitted. Oxide layers 140 and 150 may be fusion bonded to join cap 160 to device wafer layer 130. Cap 160 may include recess 152 defined by sidewalls or edges 154. Edges 154 may be flat or have other shapes.

Again, other embodiments of the present invention may provide pressure sensors having a recess that is narrower in at least one direction than a backside cavity. An example is shown in the following figure.

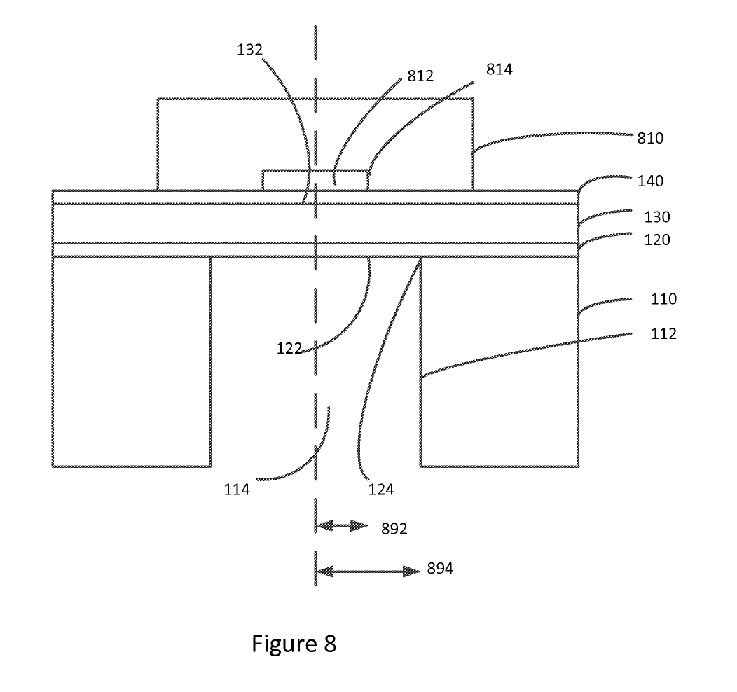

FIG. 8 illustrates a side view of a pressure sensor according to an embodiment of the present invention. In this example, cap 810 may be attached to a top side of device wafer layer 130. Cap 810 may include a recess 812 defining edges 814. Recess 812 may have a width that is narrower in a first direction than a width of backside cavity 114 in the same direction. That is, a distance 892 from a center line of the pressure sensor to an outside edge 814 of recess 812 may be shorter than a distance from the center line to an edge 112 of backside cavity 114. In this and other embodiments of the present invention, edges 814 may be arranged such that they fit within edge 112 of backside cavity 114, again, from a vertical point of view. Also, while in this example, recess 812 may be formed in cap 810, in other embodiments of the present invention, recess 812 may be formed in cap 810, oxide layer 140, device layer 130, or any combination thereof.

As before, various techniques may be utilized to manufacture these pressure sensors. Similar steps to those shown in FIG. 3 through FIG. 6 may be utilized to form handle wafer or layer 110, oxide layer 120, device layer or wafer 130, and oxide layer 140. Examples of how cap 810 may be formed are shown in the following figures.

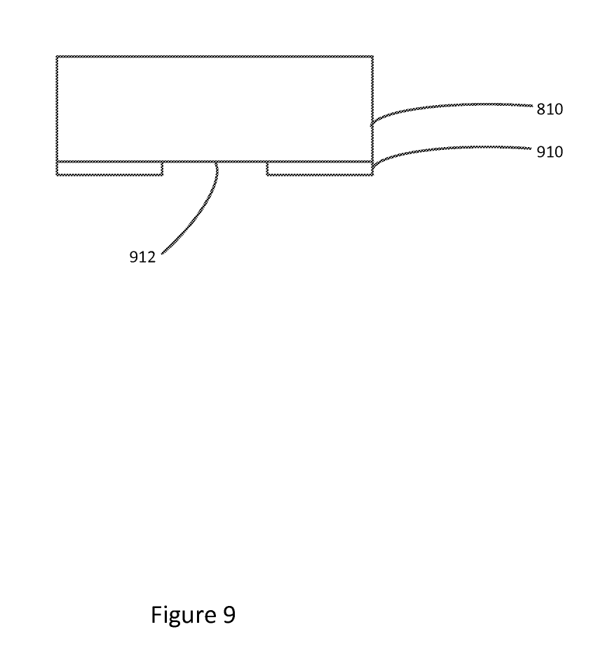

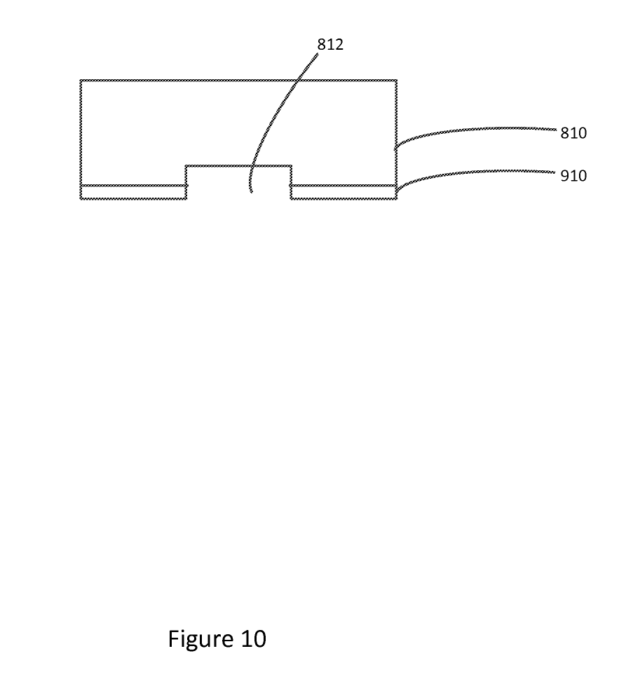

In FIG. 9, a layer of silicon nitride 910 may be deposited on a bottom side of cap 810. An opening 912 may be formed in the silicon nitride layer 910. An oxide layer may then be grown. This oxide layer may have limited growth on a silicon nitride 910, but may consume silicon not protected and exposed by opening 912. This oxide may be removed in FIG. 10 to form recess 812. The silicon nitride layer 910 may also be removed, and there the resulting cap 810 may be fusion bonded to oxide layer 140 on the top of device wafer layer 130 to form the pressure sensor shown in FIG. 8. In other embodiments of the present invention, oxide layer 140 may be omitted, and cap 810 may be bonded to device layer 130.

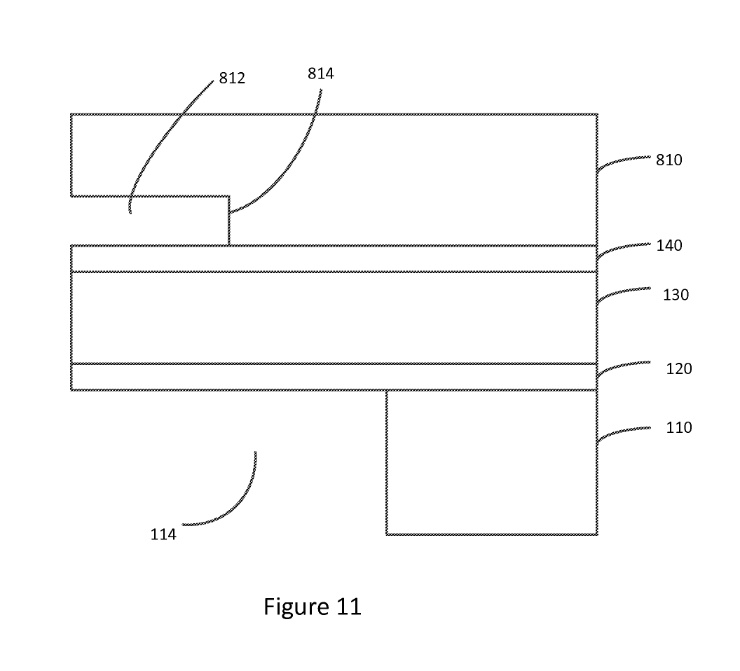

FIG. 11 illustrates a side view of a portion of a pressure sensor according to an embodiment of the present invention. As before, handle wafer or layer 110 may be used to support device wafer or layer 130. Handle wafer 110 may have a backside cavity 114 extending from a bottom of handle wafer or layer 110 to a bottom side of oxide layer 120. An oxide layer 140 may be grown on top of device wafer 130. Cap 810 may be fusion bonded to oxide layer 140. Specifically, silicon on a bottom side of cap 810 may be fusion bonded to oxide layer 140, which may have been grown on device wafer or layer 130. Again, recess 812 may be defined by edges 814. Edges 814 may be flat as shown or have other shapes.

Again, edges 814 of cavity 812 may have other shapes. An example is shown in the following figure.

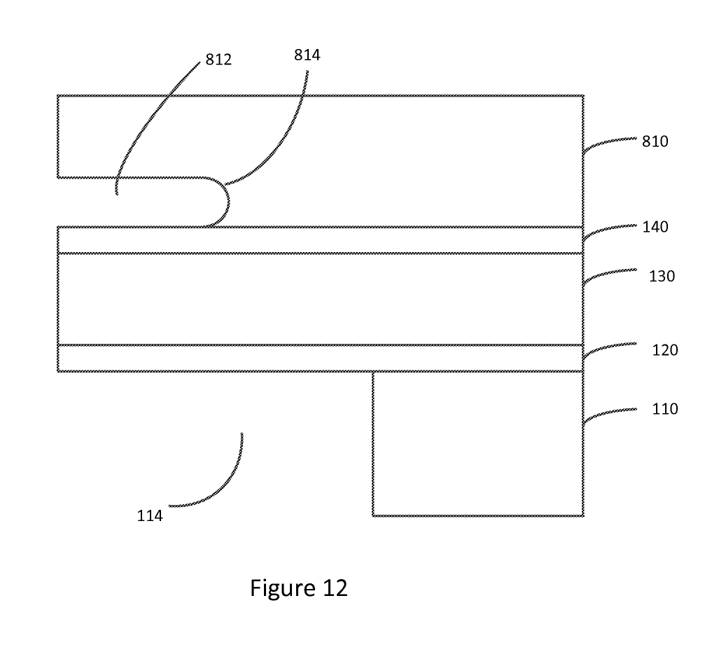

FIG. 12 illustrates an example where an edge 814 of cavity 812 may be curved. This curvature may be caused by the unidirectional consumption of silicon in cap 810 when an oxide layer is grown on a bottom side of cap 810.

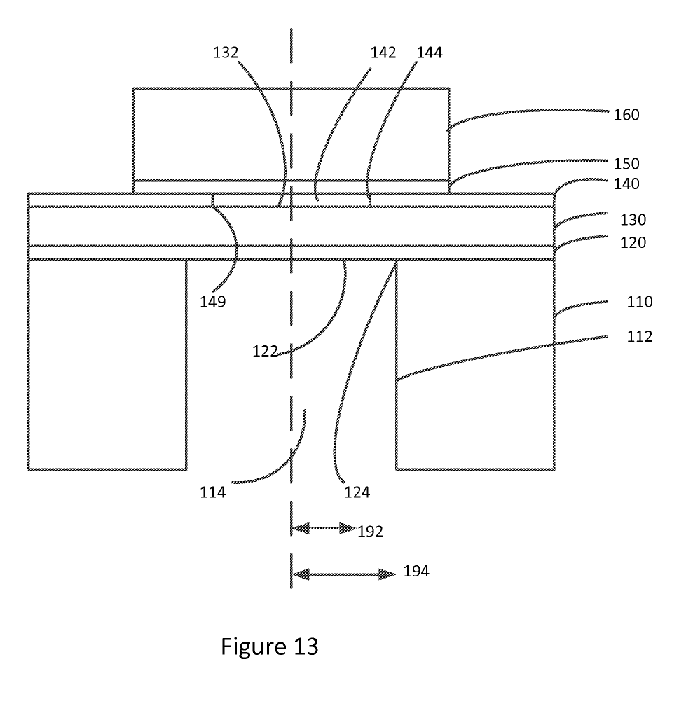

FIG. 13 illustrates a side view of another pressure sensor according to an embodiment of the present invention. As before, this pressure sensor may include cap 160 attached to a top of a first wafer portion that includes device wafer or layer 130 and handle wafer or layer 110. Device wafer of layer 130 may be supported by handle wafer or layer 110. Handle wafer or layer 110 may include a backside cavity 114 defining an edge of sidewall 112. Backside cavity 114 may extend from a bottom surface of handle wafer or layer 110 to a bottom 122 of oxide layer 120. Device layer 130 may have one or more electrical components 132 formed in its top surface. Electrical components 132 may be protected by oxide layer 140.

Cap 160 may include oxide layer 150 on a bottom surface, though in this and other embodiments of the present invention, oxide layer 150 may be omitted. Cap 160 may be attached to device layer 130 by fusion bonding oxide layer 150 to oxide layer 140. Where oxide layer 150 is not used, cap 160 may be fusion bonded directly to oxide layer 140. Oxide layer 140 may be etched before fusion bonding to form a recess, which is reference cavity 142. Etching oxide layer 140, or other oxide layer, provides an advantage in that oxide etching is traditionally a very well-controlled process step. Also, the thickness of the reference cavity may be precisely controlled by the thickness of the thermal oxide layer 140, which is also a very well-controlled process. Reference cavity 142 may be defined by outer edge 144. While in this example reference cavity is shown as extending through oxide layer 140, in various embodiments of the present invention, reference cavity 142 may extend only part way through oxide layer 140. As compared to forming a reference cavity in the cap 160 (as shown in FIG. 1), forming the reference cavity in the oxide layer 140 may simplify the alignment of cap 160 to the membrane. This may be at least partly due to the fact that cap 160 is only used to cover the reference cavity and does not itself define the reference cavity or active membrane. Also, while reference cavity 142 may be formed in oxide layer 140, in other embodiments of the present invention, reference cavity 142 may be formed in oxide layer 140, oxide layer 150, oxide layer 140, cap 160, or any combination thereof.

Reference cavity 142 may have a width that is narrower than a width of backside cavity 114 in at least one direction. Specifically, a distance 192 from a center line of the pressure sensor to an edge 144 of reference cavity 142 may be shorter than a distance 194 from a center line to an edge 112 of backside cavity 114. In this way, an active portion of a membrane defined by edge 144 may be narrower than the active membrane defined by edge 112.

In conventional pressure sensors, cap 160 may be absent, or cap 160 may have a recess that forms an opening that is wider than a corresponding backside cavity. In such case, as a membrane or diaphragm formed by a backside cavity deflects, a junction point between a diaphragm and frame may experience a large tensile force. In this figure, if cap 160 were absent, this force would be concentrated at location 124. This concentration of force may result in cracks or other damage at or near location 124.

Accordingly, as described above, embodiments of the present invention may provide a cap or other reinforcing structure, such as cap 160, where a reference cavity, such as reference cavity 142, may be narrower than a backside cavity, such as backside cavity 114. In this case, location 124 may be reinforced by cap 160. Also, the location of highest stress moves from the location 124 to location 149. The stress at location 149 is compressive when pressure is applied to the underside of membrane 122, rather than tensile. Further, even when one or more cracks or other damage appears at or near location 124, the cracks are away from the membrane area, which is defined by reference cavity 142.

Also, in conventional pressure sensors, a membrane or diaphragm may deflect an amount that may cause damage to the pressure sensor. This may occur due to the presence of unforeseen high pressures from fluids in the backside cavity, or by another event.

Accordingly, embodiments of the present invention may provide a reference cavity having height or thickness that limits a maximum deflection of the membrane. In various embodiments of the present invention, this height or thickness may be such that a membrane may be able to deflect enough for desired operation, but not enough to cause damage to the pressure sensor. Specifically, edge 144 may have a height that allows the membrane to deflect enough for proper operation of the pressure sensor, but not enough to cause damage or rupture the membrane. Instead, the membrane deflects such that it reaches a top of the reference cavity 142 and cannot go any further before damage is caused. That is, the top of the reference cavity 142 may act as a deflection stop to prevent damage to the pressure sensor. In this and other embodiments of the present invention, one or more surfaces, such as the top surface of reference cavity 142 may include one or more bosses or other structures that may act as a stop or limit on the amount that an active membrane may deflect.

Again, in various embodiments of the present invention, the structures used in pressure sensors may have various sizes and width. For example, handle wafer or portion may have a thickness of 250 to 600 microns, though it may be thinner than 250 or thicker than 600 microns. Device wafer or layer 130 may be considerable thinner since it forms the membrane. This thickness may be 15-25 microns, though it may be thinner than 15 or thicker than 25 microns. The cap wafer or layer 160, and other cap wafer or layers, may have a thickness that is at least approximately 150 microns, though it may be narrower or thicker than 150 microns. The buried or bonding oxide layers 120, 140, and 150 may have a thickness between 0.1 and 3 microns, though they may be thinner or thicker than this range. The reference cavity 142, as with the other reference cavities in other embodiments of the present invention, may have a thickness or height of 100 nm to 500 nm, though in other embodiments may it may be from 50 m to 1000 nm. A specific embodiment of the present invention may have a reference cavity having a height of 4000 A.

Again, reference cavity 142 may have a width that is narrower than a width of the backside cavity 114 in at least one direction. In this in other embodiments, reference cavity 142 may be sized and aligned such that it fits within backside cavity 114. The result is that the device membrane is defined in size by recess 142 in oxide layer 140, instead of backside cavity 114, as is conventional. An example is shown in the following figure.

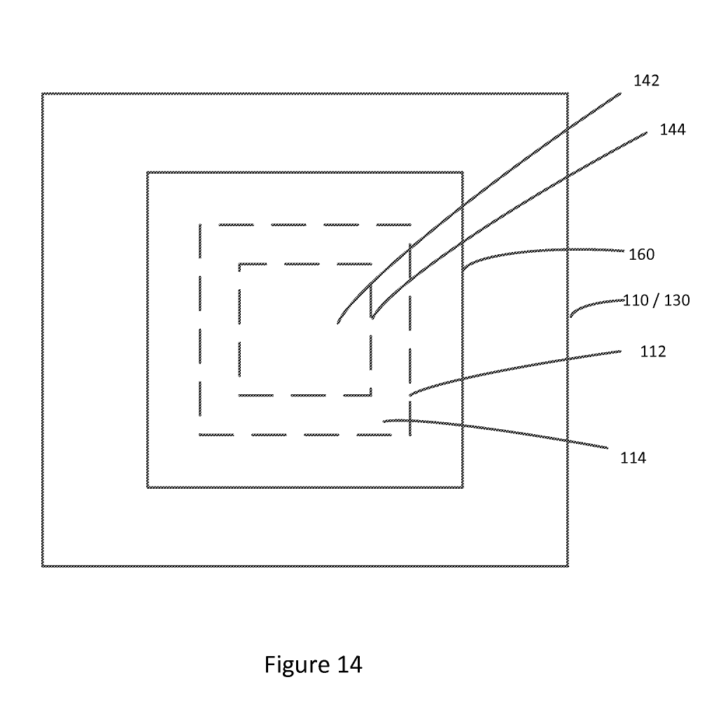

FIG. 14 illustrates a top view of a pressure sensor according to an embodiment of the present invention. Again, cap 160 may be placed on a first wafer portion including handle wafer or layer 110 and device layer or wafer 130. In this example, reference cavity 142 may have edges 144 that are arranged to fit within edges 112 of backside cavity 114. In this example, reference cavity 142 may define the area of the pressure sensor's active membrane. In various embodiments of the present invention, the active membrane may have various sizes. For example, it may be 240 by 240 microns in size. The membrane thickness may be on the order of 20 microns. Such a membrane or diaphragm may support and be able to measure pressures up to 20 bar, 120 bar, or more.

The various layers shown here may be omitted, and others may be included consistent with embodiments of the present invention. A specific example of a method of manufacturing an embodiment of the present invention is shown in the following figures.

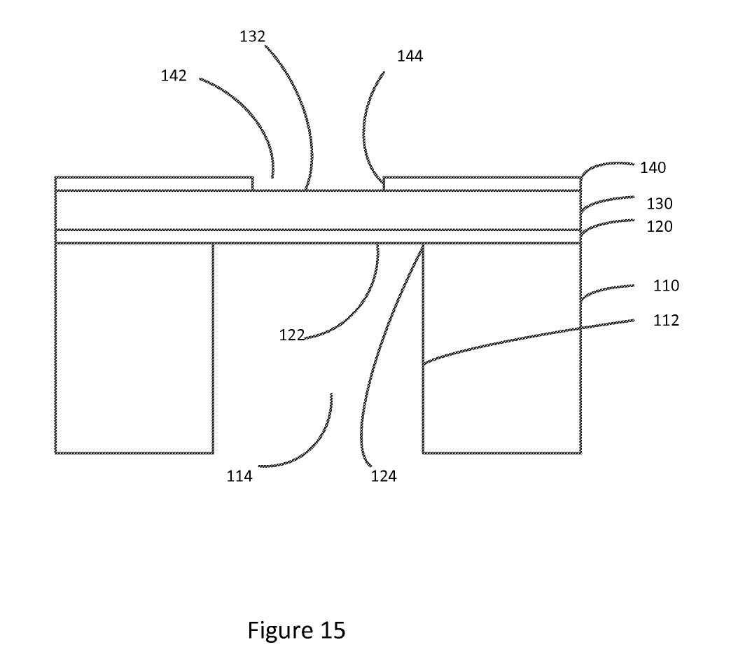

FIG. 15 illustrates a portion of a pressure sensor being manufactured. This portion may be formed in a same or similar manner as the portion shown in FIG. 4. Additionally, a recess may be formed in layer 140 that will form reference cavity 142. Again while the reference cavity 142 is shown as extending through oxide layer 140, in other embodiments of the present invention, reference cavity 142 may extend only partly though oxide layer 140. A cap 160, either with or without oxide layer 150, may be placed over reference cavity 142 to form the pressure sensor of FIG. 13.

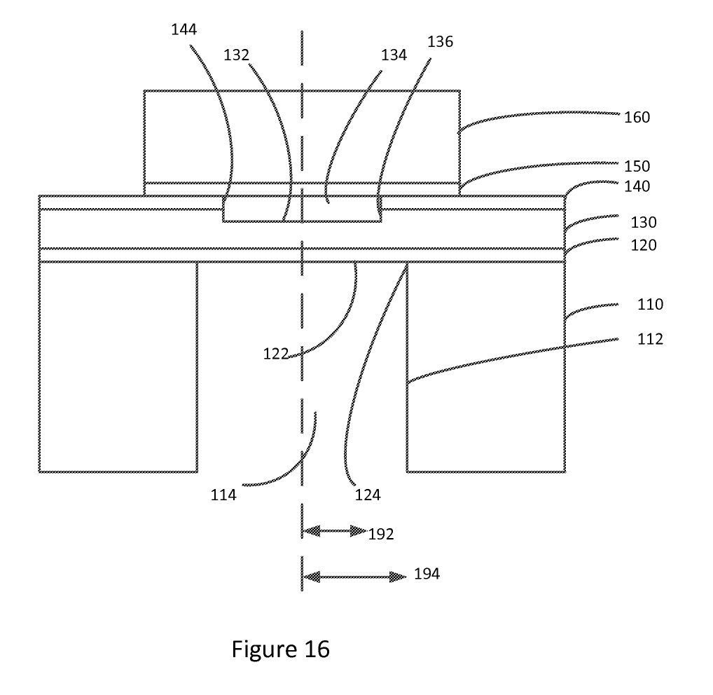

FIG. 16 illustrates a side view of another pressure sensor according to an embodiment of the present invention. As before, this pressure sensor may include cap 160 attached to a top of a first wafer portion that includes device wafer or layer 130 and handle wafer or layer 110. Device wafer of layer 130 may be supported by handle wafer or layer 110. Handle wafer or layer 110 may include a backside cavity 114 defining an edge of sidewall 112. Backside cavity 114 may extend from a bottom surface of handle wafer or layer 110 to a bottom 122 of oxide layer 120. Device layer 130 may have one or more electrical components 132 formed in its top surface. Electrical components 132 may be protected by oxide layer 140.

Cap 160 may include oxide layer 150 on a bottom surface, though oxide layer 150 may be omitted in this and other embodiments of the present invention. Cap 160 may be attached to device layer 130 by fusion bonding oxide layer 150 to oxide layer 140. Where oxide layer 150 is not used, cap 160 may be fusion bonded directly to oxide layer 140, or cap 160 may be bonded directly to device layer 130. Oxide layer 140 may be etched before fusion bonding to form a top portion of a recess, which is reference cavity 142. Device layer 130 may also be etched to form a bottom portion of reference cavity 134. Reference cavity 134 may be defined by outer edges 144 and 136. As compared to forming a reference cavity in the cap 160 (as shown in FIG. 1), forming the reference cavity in the oxide layer 140 and device layer 130 may simplify the alignment of cap 160 to the membrane. This may be at least partly due to the fact that cap 160 is only used to cover the reference cavity and does not itself define the reference cavity. Also, while reference cavity 134 is formed in the oxide layer 140 and device layer 130, in other embodiments of the present invention, oxide layer 140 may be omitted and reference cavity 134 may be formed in device layer 130.

Reference cavity 136 may have a width that is narrower than a width of backside cavity 114 in at least one direction. Specifically, a distance 192 from a center line of the pressure sensor to edge 144 and 136 of reference cavity 134 may be shorter than a distance 194 from a center line to an edge 112 of backside cavity 114. In this way, an active portion of a membrane defined by edges 144 and 136 may be narrower than the membrane defined by edge 112.

Also, in conventional pressure sensors, a membrane or diaphragm may deflect an amount that may cause damage to the pressure sensor. This may occur due to the presence of unforeseen high pressures from fluids in the backside cavity, or by another event.

Accordingly, embodiments of the present invention may provide a reference cavity having height or thickness that limits a maximum deflection of the membrane. In various embodiments of the present invention, this height or thickness may be such that a membrane may be able to deflect enough for desired operation, but not enough to cause damage to the pressure sensor. Specifically, edges 136 and 144 may have a height that allows the membrane to deflect enough for proper operation of the pressure sensor, but not enough to cause damage or rupture the membrane. Instead, the membrane deflects such that it reaches a top of the reference cavity 142 134 cannot go any further before damage is caused. That is, the top of the reference cavity 134 may act as a deflection stop to prevent damage to the pressure sensor. In this and other embodiments of the present invention, one or more surfaces, such as the top surface of reference cavity 134 may include one or more bosses or other structures that may act as a stop or limit on the amount that an active membrane may deflect.

Again, in various embodiments of the present invention, the structures used in pressure sensors may have various sizes and width. For example, handle wafer or portion may have a thickness of 250 to 600 microns, though it may be thinner than 250 or thicker than 600 microns. Device wafer or layer 130 may be considerable thinner since it forms the membrane. This thickness may be 15-25 microns, though it may be thinner than 15 or thicker than 25 microns. The cap wafer or layer 160, and other cap wafer or layers, may have a thickness that is at least approximately 150 microns, though it may be narrower or thicker than 150 microns. The buried or bonding oxide layers 120, 140, and 150 may have a thickness between 0.1 and 3 microns, though they may be thinner or thicker than this range. The reference cavity 134, as with the other reference cavities in other embodiments of the present invention, may have a thickness or height of 100 nm to 500 nm, though in other embodiments may it may be from 50 m to 1000 nm. A specific embodiment of the present invention may have a reference cavity having a height of 4000 A.

Again, reference cavity 134 may have a width that is narrower than a width of the backside cavity 114 in at least one direction. In this in other embodiments, reference cavity 134 may be sized and aligned such that it fits within backside cavity 114. The result is that the device active membrane is defined in size by reference cavity in oxide layer 140 and device layer 130, instead of backside cavity 114, as is conventional. An example is shown in the following figure.

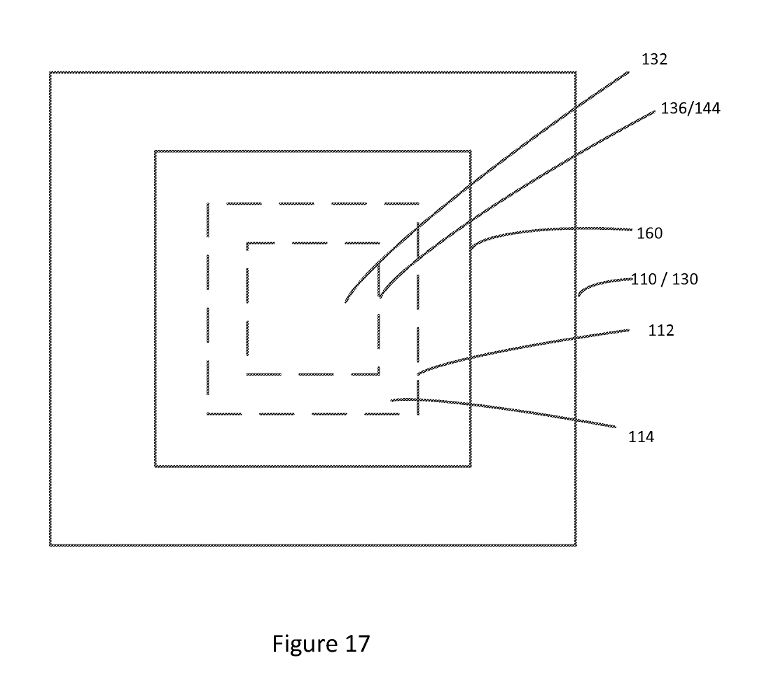

FIG. 17 illustrates a top view of a pressure sensor according to an embodiment of the present invention. Again, cap 160 may be placed on a first wafer portion including handle wafer or layer 110 and device layer 130. In this example, reference cavity 142 may have edges 144 that are arranged to fit within edges 112 of backside cavity 114. In this example, reference cavity 142 may define the area of the pressure sensor's active membrane. In various embodiments of the present invention, the active membrane may have various sizes. For example, it may be 240 by 240 microns in size. The membrane thickness may be on the order of 20 microns. Such a membrane or diaphragm may support and be able to measure pressures up to 20 bar, 120 bar, or more.

The various layers shown here may be omitted, and others may be included consistent with embodiments of the present invention. A specific example of a method of manufacturing an embodiment of the present invention is shown in the following figures.

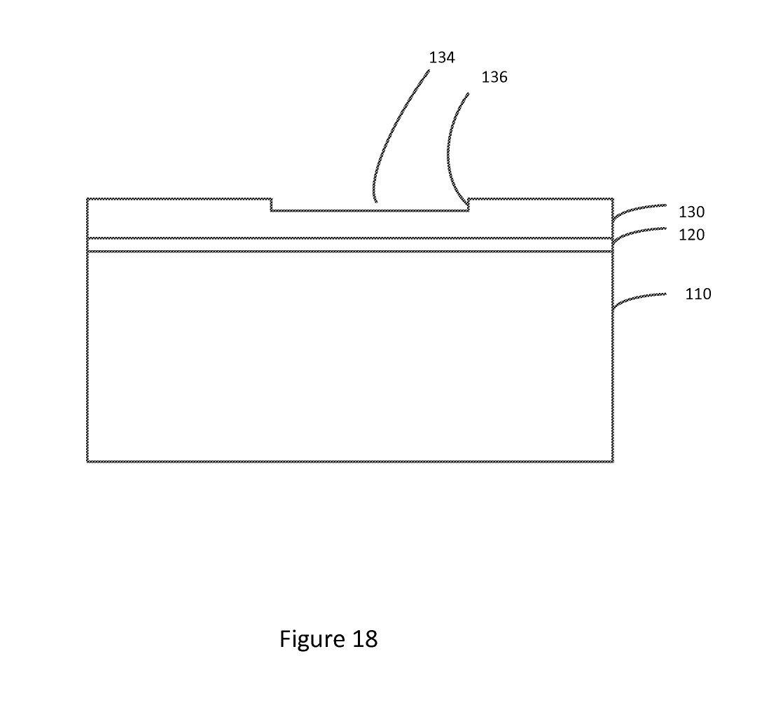

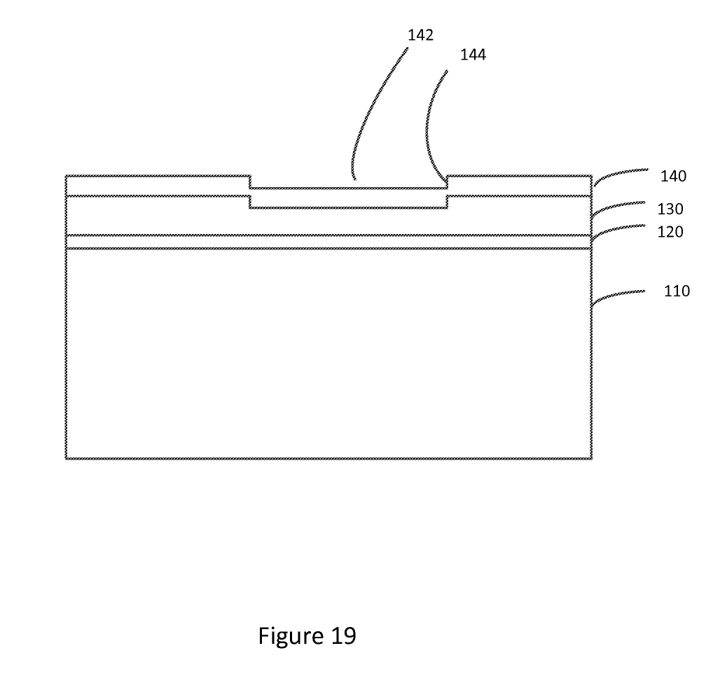

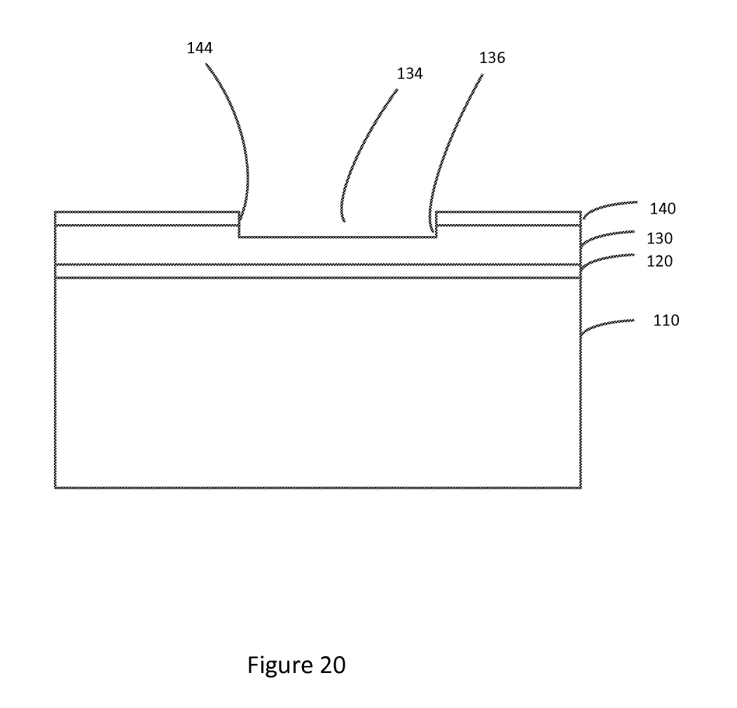

The pressure sensor portion in FIG. 18 may be formed in a same or similar manner as the pressure sensor portion of FIG. 3. Additionally, a recess may be etched in a top of device layer 130 to form a lower portion of reference cavity 134. In FIG. 19, an oxide layer 140 may be formed over device layer 130. This oxide layer may be kept in place to protect devices 132, or oxide layer 140 may be etched to form the reference cavity 134 defined by sides 144 and 136, as shown in FIG. 20.

In other embodiments of the present invention, the pressure sensor portion of FIG. 20 may be formed by growing oxide layer 140 over device layer 130, then etching through oxide layer 140 into the top of the device layer 130 to form reference cavity 134 defined by sides 144 and 136.

In other embodiments of the present invention, the membrane may include structures such as bosses, racetracks, and other structures. Examples may be found in U.S. Pat. No. 8,381,596, which is incorporated by reference. An example is shown in the following figure.

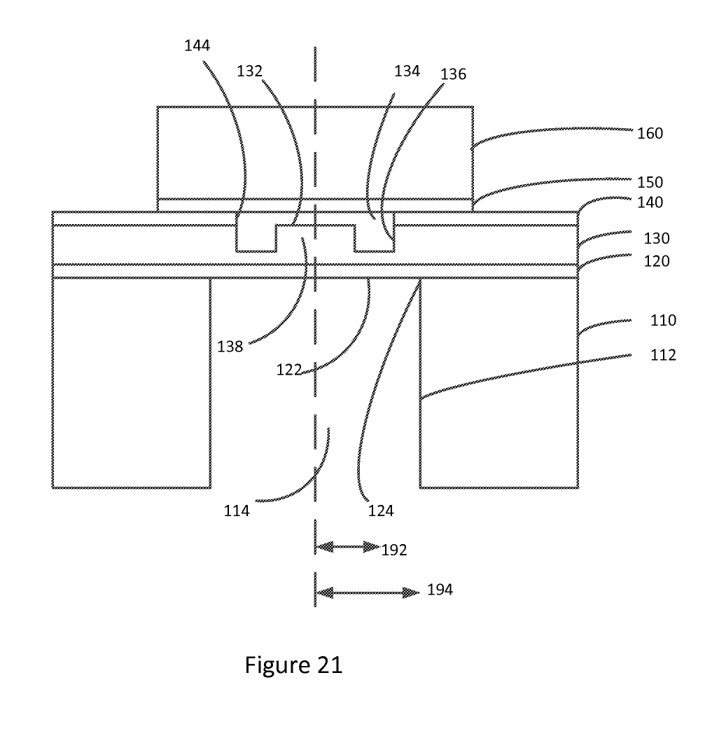

FIG. 21 illustrates a side view of another pressure sensor according to an embodiment of the present invention. As before, this pressure sensor may include cap 160 attached to a top of a first wafer portion that includes device wafer or layer 130 and handle wafer or layer 110. Device wafer of layer 130 may be supported by handle wafer or layer 110. Handle wafer or layer 110 may include a backside cavity 114 defining an edge of sidewall 112. Backside cavity 114 may extend from a bottom surface of handle wafer or layer 110 to a bottom 122 of oxide layer 120. Device layer 130 may have one or more electrical components 132 formed in boss 138, where boss 138 is an example structure formed in device layer 130. Electrical components 132 may be protected by oxide layer 140, though this is not shown here for clarity.

Cap 160 may include oxide layer 150 on a bottom surface, though oxide layer 150 may be omitted in this and other embodiments of the present invention. Cap 160 may be attached to device layer 130 by fusion bonding oxide layer 150 to oxide layer 140. Where oxide layer 150 is not used, cap 160 may be fusion bonded directly to oxide layer 140. Oxide layer 140 may be etched before fusion bonding to form a top portion of a recess, which is reference cavity 142. Device layer 130 may also be etched to form racetracks, bosses, or other structures that may form a portion of reference cavity 134. These structures may limit a maximum deflection of an active membrane to prevent damage to the device due to the presence of high pressures in backside cavity 114 or other event. Reference cavity 134 may be defined by outer edges 144 and 136. As compared to forming a reference cavity in the cap 160 (as shown in FIG. 1), forming the reference cavity in the oxide layer 140 and device layer 130 may simplify the alignment of cap 160 to the membrane. This may be at least partly due to the fact that cap 160 is only used to cover the reference cavity and does not itself define the reference cavity.

Reference cavity 136 may have a width that is narrower than a width of backside cavity 114 in at least one direction. Specifically, a distance 192 from a center line of the pressure sensor to edge 144 and 136 of reference cavity 134 may be shorter than a distance 194 from a center line to an edge 112 of backside cavity 114. In this way, an active portion of a membrane defined by edges 144 and 136 may be narrower than the membrane defined by edge 112.

In the examples above and in other embodiments of the present invention, a reference cavity may be formed in any one or more of the cap layers 810 or 160, oxide layers 150 and 140, and device layer 130. One or more of these layers may be omitted, for example oxide layer 150. Also, one or more other layers not shown may be included.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A pressure sensor comprising:
a first wafer portion having a backside cavity extending from a bottom side of the first wafer portion into the first wafer portion, the backside cavity defining an inside surface of a frame, the inside surface including a membrane;
a bonding layer over the first wafer portion; and
a cap over the first wafer portion,
wherein a reference cavity is on an opposite side of the membrane from the backside cavity where the reference cavity has a width that is narrower in at least a first dimension than a width of the backside cavity in the first dimension.

2. The pressure sensor of claim 1 wherein the cap has a recess in the bottom side to form the reference cavity.

3. The pressure sensor of claim 1 wherein the reference cavity is in the bonding layer.

4. The pressure sensor of claim 1 wherein the membrane has a recess in the top side to form the reference cavity

5. The pressure sensor of claim 1 wherein the reference cavity is in more than one of the first wafer portion, the bonding layer, and the cap.

6. The pressure sensor of claim 1 wherein the reference cavity is positioned such that vertical edges of the reference cavity are within vertical edges of the backside cavity.

7. The pressure sensor of claim 1 wherein the reference cavity has a height that limits a deflection of the membrane to prevent damage.

8. The pressure sensor of claim 1 wherein the cap is made of silicon.

9. The pressure sensor of claim 1 wherein the cap is made of borosilicate glass.

10. The pressure sensor of claim 8 wherein the bonding layer is an oxide layer.

11. The pressure sensor of claim 1 further comprising a polysilicon layer between the first wafer portion and the bonding layer.

12. A pressure sensor comprising:
a first wafer portion having a backside cavity extending from a bottom side of the first wafer portion into the first wafer portion, the backside cavity defining an inside surface of a frame, the inside surface including a membrane;
a bonding layer on a top surface of the first wafer portion; and
a cap over the first wafer portion,
wherein a reference cavity is below the cap and where the reference cavity has a width that is narrower in at least a first dimension than a width of the backside cavity in the first dimension.

13. The pressure sensor of claim 12 wherein the reference cavity is in the bonding layer.

14. The pressure sensor of claim 12 wherein the reference cavity is in the bonding layer and the first wafer portion.

15. The pressure sensor of claim 12 wherein the reference cavity is in at least one of the bonding layer and the first wafer portion.

16. The pressure sensor of claim 15 wherein the reference cavity is positioned such that vertical edges of the reference cavity are within vertical edges of the backside cavity.

17. The pressure sensor of claim 12 wherein the reference cavity has a height that limits a deflection of the membrane to prevent damage.

18. The pressure sensor of claim 12 further comprising a polysilicon layer between the first wafer portion and the bonding layer.

19. A pressure sensor comprising:
a handle wafer;
a device wafer joined to the handle wafer by a first bonding layer, where the handle wafer has a backside cavity extending from a bottom surface to the first bonding layer; and
a cap joined to the device wafer by a second bonding layer,
wherein a reference cavity is below the cap and where the reference cavity has a an outer edge that fits within an outer edge of the backside cavity.

20. The pressure sensor of claim 19 wherein the second bonding layer is as an oxide layer on the top surface of the device layer.

21. The pressure sensor of claim 19 wherein the reference cavity is in the second bonding layer.

22. The pressure sensor of claim 19 wherein the reference cavity is in the second bonding layer and the first wafer portion.

23. The pressure sensor of claim 19 wherein the reference cavity is in at least one of the second bonding layer and the first wafer portion.

24. The pressure sensor of claim 19 wherein the reference cavity has a height that limits a deflection of the membrane to prevent damage.

25. The pressure sensor of claim 19 further comprising a polysilicon layer between the device wafer and the bonding layer.
